(19) United States
(12) Patent Application Publication
(10) Pub. No.: US 2026/0358415 A1
(43) Pub. Date: Nov. 12, 2026

(54) INTEGRATED CIRCUIT, AUTOMATED TEST EQUIPMENT AND METHOD FOR TESTING A DEVICE UNDER TEST, USING ON-CHIP CONNECTIONS BETWEEN VOLTAGE PROVIDER CIRCUITS

(71) Applicant: Advantest Corporation, Marunouchi, Chiyoda-ku, Tokyo (JP)

(72) Inventors: Rudi BAUER, Eiselfing (DE); Franz ROTTNER, Wasserburg (DE); Alois THALMAIER, Reichertsheim (DE); Korbinian STIEGLBAUER, Soyen (DE)

(21) Appl. No.: 19/486,486

(22) PCT Filed: May 24, 2023
(86) PCT No.: PCT/EP2023/063984

§ 371 Date: Nov. 21, 2025

(51) Int. Cl. G01R 31/319; G01R 31/3167; G01R 31/317; G01R 35/00

(52) U.S. Cl. CPC G01R 31/31924; G01R 31/3167; G01R 31/31721; G01R 35/007

(57) ABSTRACT

Embodiments according to the invention comprise an integrated circuit for testing a device under test, comprising a first voltage provider circuit configured to provide a first voltage and a second voltage provider circuit configured to provide a second voltage, wherein the first voltage provider circuit is configured to regulate the first voltage with respect to a first reference signal, which is present on a first reference signal line, wherein the second voltage provider circuit is configured to regulate the second voltage with respect to a second reference signal, which is present on a second reference signal line and wherein the second voltage provider circuit is configured to switchably couple the second reference signal line with a first power sense input of the first voltage provider circuit via an on-chip connection, such that the second reference signal is determined by a potential of the first power sense input of the first voltage provider circuit. Furthermore, respective automated test equipments and methods for testing a device under test are disclosed.

### TECHNICAL FIELD

Embodiments according to the invention are related to integrated circuits, automated test equipments and methods for testing a device under test, using on-chip connections between voltage provider circuits.

Embodiments according to the invention are related to mixed-signal-ASIC modes and switches optimized for testing Battery Management Systems and/or for precision differential voltage force and measure.

Embodiments according to the invention are related to an economic approach to meet high precision together with high voltage requirements.

### BACKGROUND OF THE INVENTION

The test of precision high voltage components drive test costs high, because absolute accuracy is becoming inherently more challenging with higher voltage levels.

According to conventional solutions, to work around actual test system restrictions, one approach is to add a precision resistive ladder onto the load board, providing accurate voltage references to the DUT (device under test). By nature, these resistive dividers have a quite high source impedance and are therefore prone to errors caused by unknown currents flowing into the DUTs. Keeping the ladder's impedance low, would cause high power dissipation, which in turn increases the challenge of low temperature coefficient of the ladder. Calibration needs to be done by a high precision DMM (e.g. digital multimeter), connected through a suitable multiplexer to the ladder's taps. These precision DMMS are increasing test system cost significantly->Calibration is difficult, because access of high precision DMM to many single channels is not feasible in production. Expensive relay matrices need to be added to the load boards.

Another approach could be, to install VI cards (e.g. voltage-current (VI) source card) with all floating channels. But, this would cut down channel count per space by 50% and thus, again, increase test cost.

The required accuracy can, for example (e.g. with conventional approaches), not be provided with voltage ranges around 150V:200 uV (e.g. at a voltage of between 100V and 200V with an accuracy of +/−200 μV), or even as low as 50 uV @ 150V (e.g. at a voltage of between 100V and 200V with an accuracy of +/−50 μV)->roughly 1.2 to 0.3 ppm.

Typically, floating differential voltmeters are able to provide the required accuracy. However, these are expensive resources, which are rare in a test system, and therefore need to be shared among several DUT pins; These are not available in parallel, unfortunately.

The test approach using resistor ladder is introducing problems: DUT input currents are introducing voltage errors, which cannot be calibrated (or can, for example, only be calibrated with major effort): Low impedance ladder could improve; Low impedance ladder means high power dissipation and therefore extraordinary TK requirements (e.g. temperature coefficient requirements).

Therefore, it is desired to get a concept for device testing, which provides a better compromise between voltage and/or current accuracy at high voltages, calibration effort, calibration costs, and a versatility and complexity of a respective integrated circuit or automated test equipment for performing the device testing.

This is achieved by the subject matter of the independent claims of the present application.

Further embodiments according to the invention are defined by the subject matter of the dependent claims of the present application.

### SUMMARY OF THE INVENTION

Embodiments according to the invention comprise an integrated circuit for testing a device under test, comprising a first, e.g. ground-based, e.g. a ground referenced, voltage provider circuit configured to provide a first, e.g. output, voltage (e.g. +10V; e.g. for testing the DUT; e.g. via a first power line) and a second, e.g. ground-based, e.g. a ground referenced, voltage provider circuit configured to provide a second, e.g. output, voltage (e.g. +15V; e.g. for testing the DUT; e.g. via a second power line).

Furthermore, the first voltage provider circuit is configured to regulate the first voltage (e.g. by regulating a voltage present at a first power sense input) with respect to a first reference signal (e.g. +5V), e.g. using a first power sense input, which is present on a first reference signal line, e.g. such that the voltage present at the first power sense input is in a predetermined relationship with the voltage of the first reference signal. Moreover, the second voltage provider circuit is configured to regulate the second voltage with respect to a second reference signal (e.g. +10V), which is present on a second reference signal line.

In addition, the second voltage provider circuit is configured to switchably, e.g. selectively, e.g. selectably, couple the second reference signal line with a first power, e.g. positive, sense input of the first voltage provider circuit via an on-chip connection, for example, via an on-chip switch, such that the second reference signal is determined by a potential of the first power sense input of the first voltage provider circuit.

Embodiments according to the invention are based on the idea to provide high output voltages with high accuracy based on an on-chip coupling of a plurality of voltage provider circuits. The inventors recognized that the coupling of the second reference signal line with the first power sense input of the first voltage provider circuit allows incorporating an offset for the regulation of the second voltage, so that the regulation can be performed in a limited voltage range, allowing high accuracy, whilst still being able to provide a high output voltage.

At the same time, a complexity of the integrated circuit is kept low and a versatility of the integrated circuit is kept high by implementing the coupling functionality using on-chip connections, e.g. with on-chip switches. As an example, for high maximum output voltages, a large number of voltage provider circuits may be stacked, so that a respective voltage provider circuit is configured to couple its reference signal line with a power sense input of a preceding, e.g. lower output voltage, voltage provider circuit. Therefore, according to embodiments, respective switches for implementing the coupling of the voltage provider circuits may be integrated in the integrated circuit, hence being implemented as on-chip switches, in order to keep the complexity of the testing setup low. Accordingly, a wiring effort on a respective loadboard is significantly reduced.

Furthermore, the on-chip switches allow for an easy reconfiguration of the voltage provider circuits to perform a plurality of different tasks, e.g. apart from the high voltage-high accuracy use case as explained above.

According to embodiments of the invention, the first voltage provider circuit is configured to switchably, e.g. selectively, e.g. selectably, couple the second reference signal line with the first power, e.g. positive, sense input of the first voltage provider circuit via an on-chip connection, for example via an on-chip switch, such that the second reference signal is determined by a potential of the first power sense input of the first voltage provider circuit. The first voltage provider circuit may, for example, comprise additional on-chip switches, which may increase a number of measurement modes provided, for example because of an increased number of signal routing possibilities. Hence, a versatility of the integrated circuit may be increased.

According to embodiments of the invention, the first voltage provider circuit is configured to switchably, e.g. selectively, e.g. selectably, couple the first reference signal line, via an on-chip connection, for example via an on-chip switch, with a first ground sense input of the first voltage provider circuit, wherein, for example, the first ground sense input of the first voltage provider circuit may be coupled with an external connection (e.g. a pin or a solder ball, or the like) of the integrated circuit. Alternatively or in addition, the second voltage provider circuit is configured to switchably, e.g. selectively, e.g. selectably, couple the second reference signal line, via an on-chip connection, for example via an on-chip switch, with a second ground sense input of the second voltage provider circuit, wherein, for example, the second ground sense input of the second voltage provider circuit may be coupled with an external connection (e.g. a pin or a solder ball, or the like) of the integrated circuit. Hence, additional measurement modes may be provided.

According to embodiments of the invention, the first and second voltage provider circuit are configured to switchably couple respective reference signal lines with a shared common ground reference line of the integrated circuit. This may allow for a low complexity ground reference implementation. The voltage provider circuits may be coupled on-chip with the common ground reference.

According to embodiments of the invention, the first voltage provider circuit is configured to switchably, e.g. selectively, e.g. selectably, couple the first reference signal line, via an on-chip connection, for example via an on-chip switch, with the second reference signal line of the second voltage provider circuit. Alternatively or in addition, the second voltage provider circuit is configured to switchably, e.g. selectively, e.g. selectably, couple the second reference signal line, via an on-chip connection, for example via an on-chip switch, with the first reference signal line of the first voltage provider circuit. This may allow providing additional testing functionalities, e.g. in the form of a stack of voltage provider circuits wherein one of the circuits acts as an offset generator.

According to embodiments of the invention, the first voltage provider circuit comprises a previous circuit stacking connection (e.g. for connection with a previous voltage provider circuit, e.g. for connection with a subsequent circuit stacking connection of a previous voltage provider circuit) and a subsequent circuit stacking connection (e.g. for connection with a subsequent voltage provider circuit; e.g. for connection with a previous circuit stacking connection of a subsequent voltage provider circuit). Furthermore, the first voltage provider circuit comprises a first reference signal switch configured to switchably connect the first reference signal line of the first voltage provider circuit with the previous circuit stacking connection (and, as an optional feature, alternatively with a ground sense input, and the first voltage provider circuit comprises a first routing switch configured to switchably connect the previous circuit stacking connection with the subsequent circuit stacking connection. In addition, the first voltage provider circuit comprises a first sense signal switch configured to switchably connect the subsequent circuit stacking connection with the first power sense input. Hence, a fully coupled and even switchably coupled stack of voltage provider circuits may be provided, for providing a plurality of output voltages, e.g. with increasing absolute value. Hence, a high output voltages with high accuracy may be provided.

According to embodiments of the invention, the first voltage provider circuit comprises a first control unit (e.g. a regulating unit; e.g. a closed loop control unit), wherein the first control unit is configured to provide a first analogue control signal based on a digital control, and wherein the first control unit is configured to provide the first analogue control signal for regulating the first voltage based on the potential of the first power sense input and based on the first reference signal, e.g. based on an error signal which is determined based on the first power sense input and based on the first reference signal. The inventors recognized that a respective voltage force accuracy, e.g. an accuracy of the first, e.g. output, voltage may be achieved using a digital control loop. Therefore, the signals measured at the first power sense input and the first reference signal line (which may be switchably coupled via an on-chip connection with a power sense input of a preceding, e.g. lower voltage, voltage provider circuit) may be measured precisely. The inventors recognized that using such a control unit, an “imprecise” analog voltage feedback may be improved using the digital control loop, in order to correct remaining errors of the analog feedback. Hence, an extreme force-precision may be achieved.

According to embodiments of the invention, the first voltage provider circuit comprises a first differential amplifier, wherein a first input, e.g. a positive input, of the first differential amplifier is coupled with the first power sense input of the first voltage provider circuit. Furthermore, a second input, e.g. a negative input, of the first differential amplifier is coupled with the first reference signal line and the first control unit is configured to provide the first analogue control signal based on an output of the first differential amplifier. The amplifier may allow a robust and low cost implementation of a regulating circuit according to embodiments.

According to embodiments of the invention, the first differential amplifier is ground referenced, e.g. having a ground or ground earth based reference potential, wherein, for example, differential amplifiers of different voltage provider circuits, which are implemented on a common chip, are coupled to a same ground reference. Hence, low cost amplifiers may be used. Furthermore, the usage of ground-based amplifiers may allow providing high common modes. Hence, the inventor recognized that this may allow for the following features: High force range decoupled from small measurement range, higher measurement precision, lower drift and/or no shared resources.

According to embodiments of the invention, the first differential amplifier is highly linear, such that, for example, a non-linearity of the differential amplifier is smaller than or equal to 10 parts per million. Alternatively or in addition, the first differential amplifier is insensitive to high offset voltages (e.g. high common mode voltages; e.g. such that a gain of the differential amplifier does not change by more than 0.1% or 0.01%, or 0.001% for a variation of the common mode voltage by at least 10V). Alternatively or in addition, the integrated circuit is configured to at least partially compensate a common mode error of the differential amplifier, e.g. using a coarse quantization of a common mode voltage and a common mode, e.g. such that the compensated differential amplifier is insensitive to high offset voltages. Hence, voltages may be measured with high resolution, independent, or at least approximately independent, of high offset voltage potentials.

As an example, after calibration up to 160 V common mode may be achieved with a resulting offset in the range of several, e.g. 1 to 10, uV, e.g. μV. As an example, gain mismatch may be the main error source in the differential amplifier.

According to embodiments of the invention, the first control unit is configured to digitize an analogue output signal of the first differential amplifier and to provide a first analogue control signal based on a digital control of the digitized output signal of the first differential amplifier.

According to embodiments of the invention, the first voltage provider circuit comprises a first output unit, wherein the first output unit is configured to offset the analogue control signal or an amplified version thereof, based on an offset signal, e.g. of the first voltage provider circuit, e.g. provided by an offset signal line, e.g. in dependence on a potential of the reference signal line, e.g. such that a deviation of a potential of the offset analogue signal, which may, for example, be input into a buffer circuit, from a potential of the reference signal line is determined by the analogue control signal. The offset signal may be determined by a signal on the respective reference signal line (e.g. using a switchable coupling) and may hence allow providing the high output voltage, by offsetting the analogue control signal or an amplified version thereof provided by the control unit. Hence, low voltage range control with high accuracy may be combined with high absolute voltage.

According to embodiments of the invention, the first output unit comprises a first pre-amplifier, a first adder, a first output amplifier, and a first offset signal line, wherein the first output unit is configured to amplify the first analogue control signal using the pre-amplifier, to offset the analog control signal or an amplified version thereof using the adder, e.g. using an voltage adder, based on the offset signal which is provided by the offset signal line, and to amplify the offset amplified analogue control signal or the amplified version thereof using the output amplifier in order to provide the first voltage. The inventors recognized that this specific implementation of the first output unit may be efficient and robust.

According to embodiments of the invention, the pre-amplifier and/or the output amplifier are ground referenced, e.g. having a ground or ground earth based reference potential; wherein, for example, differential amplifiers of different voltage provider circuits, which are implemented on a common chip, are coupled to a same ground reference. Hence, as explained above, low cost amplifiers may be used. Accordingly, usage of ground-based amplifiers may allow providing high common modes. As explained before, this may allow for the following features: High force range decoupled from small measurement range, higher measurement precision, lower drift and/or no shared resources.

According to embodiments of the invention, the first voltage provider circuit is configured to switchably, e.g. selectively, e.g. selectably, couple the first offset line with the first reference signal line via an on-chip connection, for example, via an on-chip switch. Hence, an efficient offset provision method may be implemented to combine high regulation accuracy with high output voltage.

According to embodiments of the invention, the first voltage provider circuit is configured to switchably, e.g. selectively, e.g. selectably, couple the first offset line with a ground reference potential, e.g. earth. This may allow providing additional device testing modes and hence, increase the flexibility of the integrated circuit.

According to embodiments of the invention, the integrated circuit comprises one or more further voltage provider circuits, wherein a respective voltage provider circuit of the one or more further voltage provider circuits is configured to provide a respective further, e.g. output, voltage, and wherein a respective voltage provider circuit of the one or more further voltage provider circuits is configured to regulate a respective further voltage with respect to a respective reference signal, e.g. +10V, which is present on a respective reference signal line of the respective further voltage provider circuit. Hence, a plurality of output voltages may be provided for testing, for example, a stack of DUTs. In addition, a high maximum output voltage may be provided.

According to embodiments of the invention, the first voltage provider circuit, the second voltage provider circuit and the one or more further voltage provider circuits are coupled as a stack. Hence, stacked DUTs, e.g. DUTs with a stacked configuration (e.g. having a plurality of subunits that are coupled in a stacked manner with each other, e.g. having respective sub-inputs and sub-outputs in a stacked arrangement), may be tested efficiently.

According to embodiments of the invention, a given one of the voltage provider circuits is configured to switchably, e.g. selectively, e.g. selectably, couple its power, e.g. positive, sense input to a reference signal line of a subsequent voltage provider circuit via an on-chip connection, for example, via an on-chip switch. In addition, the given one of the voltage provider circuits is configured to switchably, e.g. selectively, e.g. selectably, couple its power, e.g. positive, sense input to a reference signal line of a preceding voltage provider circuit via an on-chip connection, for example, via an on-chip switch, e.g. such that reference signals of the preceding voltage provider circuit and of the subsequent voltage provider circuit are determined by a potential at the power sense input of the given voltage provider circuit and, for example, such that reference signals of the preceding voltage provide circuit and of the subsequent voltage provider circuit can be set to a desired value using an appropriate setting of an output voltage at an output of the given one of the voltage provider circuits, for example, provided that the output of the given one of the voltage provider circuits is coupled to the power sense input of the given one of the voltage provider circuits. Hence, a plurality of voltage provider circuits may be coupled as explained in the context of the first and second voltage provider circuit. Accordingly, each voltage provider circuit may optionally comprise any or all of the features and functionalities as disclosed in the context of the first and/or second voltage provider circuit (e.g. control unit, output unit, respective amplifiers offset signals and digital control loops) both individually and taken in combination.

In the following embodiments according to the invention, which enable the provision of a plurality of specific device testing modes are disclosed. These embodiments allow, inter alia, providing extensive device testing functionalities with good flexibility and/or efficiency.

According to embodiments of the invention, the given one of the voltage provider circuits is configured to switchably couple its power sense input to one out of a reference signal line of the preceding voltage provider circuit and the reference signal line of the subsequent voltage provider circuit in a first state, e.g. to either the reference signal line of the preceding voltage provider circuit or the reference signal line of the subsequent voltage provider circuit. In addition, the given one of the voltage provider circuits is configured to switchably couple its power sense input to both the reference signal line of the preceding voltage provider circuit and the reference signal line of the subsequent voltage provider circuit in a second state, such that reference signals of the preceding voltage provider circuit and of the subsequent voltage provider circuit are determined by a potential at the power sense input of the given voltage provider circuit.

According to embodiments of the invention, a given one of the voltage provider circuits is configured to switchably, e.g. selectively, e.g. selectably, establish a route between a reference signal line of a preceding voltage provider circuit and a reference signal line of a subsequent reference signal line (e.g., such that reference signal lines of the preceding voltage provider circuit and of the subsequent voltage provider circuit are coupled) (e.g. such that reference signal lines of the preceding voltage provider circuit and of the subsequent voltage provider circuit are coupled while a reference signal line of the given voltage provider circuit is not coupled to the reference signal lines of the preceding voltage provider circuit and of the subsequent voltage provider circuit but coupled to a different potential, e.g. to a ground sense input, and wherein, for example, a potential of the reference signal lines of the preceding voltage provider circuit and of the subsequent voltage provider circuit is determined by the given voltage provider circuit) (e.g. such that reference signal lines of the preceding voltage provider circuit, of the given voltage provider circuit and of the subsequent voltage provider circuit are coupled; e.g. such that reference signal lines of the preceding voltage provider circuit, of the given voltage provider circuit and of the subsequent voltage provider circuit are all coupled to a potential which is different from a ground potential, and which may, for example, be provided by yet another voltage provider circuit) (e.g. such that reference signal lines of the preceding voltage provider circuit, of the given voltage provider circuit and of the subsequent voltage provider circuit form a common signal line) (e.g. such that reference signal lines of the preceding voltage provider circuit, of the given voltage provider circuit and of the subsequent voltage provider circuit form an uninterrupted on-chip reference signal line).

According to embodiments of the invention, a given one of the voltage provider circuits comprises a previous circuit stacking connection (e.g. for connection with a previous voltage provider circuit, e.g. for connection with a subsequent circuit stacking connection of a previous voltage provider circuit) and a subsequent circuit stacking connection (e.g. for connection with a subsequent voltage provider circuit; e.g. for connection with a previous circuit stacking connection of a subsequent voltage provider circuit), wherein the given voltage provider circuit comprises a reference signal switch configured to switchably connect the reference signal line of the given voltage provider circuit with the previous circuit stacking connection of the given voltage provider circuit, and, as an optional feature, alternatively with a ground sense input. Furthermore, the given voltage provider circuit comprises a routing switch configured to switchably connect the previous circuit stacking connection of the given voltage provider circuit with the subsequent circuit stacking connection of the given voltage provider circuit, and the given voltage provider circuit comprises a sense signal switch configured to switchably connect the subsequent circuit stacking connection of the given voltage provider circuit with a power sense input of given voltage provider circuit.

According to embodiments of the invention, the integrated circuit or an automated test equipment comprising the integrated circuit is configured to set the given voltage provider circuit in a first configuration by controlling the reference signal switch, the routing switch and the sense signal switch of the given voltage provider circuit, so that the reference signal line of the given voltage provider circuit is connected with the previous circuit stacking connection of the given voltage provider circuit, but so that the reference signal line of the given voltage provider circuit is unconnected with a ground sense input of the given voltage provider circuit, using the reference signal switch, and so that the previous circuit stacking connection of the given voltage provider circuit is unconnected with (for example disconnected from, for example electrically separated from) the subsequent circuit stacking connection of the given voltage provider circuit, using the routing switch, but so that the power sense input of the given voltage provider circuit is connected with the subsequent circuit stacking connection of the given voltage provider circuit, using the sense switch.

According to embodiments of the invention, the integrated circuit or an automated test equipment comprising the integrated circuit is configured to set the given voltage provider circuit in a second configuration by controlling the reference signal switch, the routing switch and the sense signal switch of the given voltage provider circuit, so that the reference signal line of the given voltage provider circuit is unconnected with the previous circuit stacking connection of the given voltage provider circuit, but so that the reference signal line of the given voltage provider circuit is connected with a ground sense input of the given voltage provider circuit using the reference signal switch, and so that the previous circuit stacking connection of the given voltage provider circuit is unconnected with the subsequent circuit stacking connection of the given voltage provider circuit, using the routing switch, but so that the power sense input of the given voltage provider circuit is connected with the subsequent circuit stacking connection of the given voltage provider circuit, using the sense switch.

According to embodiments of the invention, integrated circuit or an automated test equipment comprising the integrated circuit is configured to set the given voltage provider circuit in a third configuration by controlling the reference signal switch, the routing switch and the sense signal switch of the given voltage provider circuit, so that the reference signal line of the given voltage provider circuit is connected with the previous circuit stacking connection of the given voltage provider circuit, but so that the reference signal line of the given voltage provider circuit is unconnected with a ground sense input of the given voltage provider circuit using the reference signal switch, and so that the previous circuit stacking connection of the given voltage provider circuit is unconnected with the subsequent circuit stacking connection of the given voltage provider circuit, using the routing switch, and so that the power sense input of the given voltage provider circuit is unconnected with the subsequent circuit stacking connection of the given voltage provider circuit, using the sense switch.

According to embodiments of the invention, the integrated circuit or an automated test equipment comprising the integrated circuit is configured to set the given voltage provider circuit in a fourth configuration by controlling the reference signal switch, the routing switch and the sense signal switch of the given voltage provider circuit, so that the reference signal line of the given voltage provider circuit is unconnected with the previous circuit stacking connection of the given voltage provider circuit, but so that the reference signal line of the given voltage provider circuit is connected with a ground sense input of the given voltage provider circuit, using the reference signal switch, and so that the previous circuit stacking connection of the given voltage provider circuit is connected with the subsequent circuit stacking connection of the given voltage provider circuit, using the routing switch, and so that the power sense input of the given voltage provider circuit is connected with the subsequent circuit stacking connection of the given voltage provider circuit, using the sense switch.

According to embodiments of the invention, the integrated circuit or an automated test equipment comprising the integrated circuit is configured to set the given voltage provider circuit in a fifth configuration by controlling the reference signal switch, the routing switch and the sense signal switch of the given voltage provider circuit, so that the reference signal line of the given voltage provider circuit is connected with the previous circuit stacking connection of the given voltage provider circuit, but so that the reference signal line of the given voltage provider circuit is unconnected with a ground sense input of the given voltage provider circuit, using the reference signal switch, and so that the previous circuit stacking connection of the given voltage provider circuit is connected with the subsequent circuit stacking connection of the given voltage provider circuit, using the routing switch, and so that the power sense input of the given voltage provider circuit is unconnected with the subsequent circuit stacking connection of the given voltage provider circuit, using the sense switch.

According to embodiments of the invention, the first voltage provider circuit, the second voltage provider circuit and the one or more further voltage provider circuits are coupled as a stack, wherein the first, the second and the one or more further voltage provider circuits are structurally and/or functionally identical (e.g. having same sub-circuits; e.g. being configured to provide a same set of functionalities) voltage provider circuits, wherein the integrated circuit or an automated test equipment comprising the integrated circuit is configured (and/or is, for example, adapted) to configure the voltage provider circuits of the stack such that a plurality of successive, e.g. subsequent, voltage provider circuits arranged in the stack provide output voltages in an increasing order, wherein a subsequent circuit stacking connection of a respective voltage provider circuit of the stack is, e.g. configured to be, coupled via an on chip-connection with a previous circuit stacking connection of a respective subsequent higher voltage voltage provider circuit of the stack, wherein the integrated circuit or an automated test equipment comprising the integrated circuit is configured to set a certain voltage provider circuit of the stack to the second configuration, and to set a plurality of, with regard to the certain voltage provider circuit of the stack, immediately subsequent higher voltage voltage provider circuits to the first configuration.

According to embodiments of the invention, the first voltage provider circuit, the second voltage provider circuit and the one or more further voltage provider circuits are coupled as a stack, wherein the first, the second and the one or more further voltage provider circuits are structurally and/or functionally identical (e.g. having same sub-circuits; e.g. being configured to provide a same set of functionalities) voltage provider circuits, wherein the integrated circuit or an automated test equipment comprising the integrated circuit is configured (and/or is, for example, adapted) to configure the voltage provider circuits of the stack, such that a plurality of successive, e.g. subsequent, voltage provider circuits arranged in the stack provide output voltages in an increasing order, wherein a subsequent circuit stacking connection of a respective voltage provider circuit of the stack is (e.g. configured to be) coupled via an on chip-connection with a previous circuit stacking connection of a respective subsequent higher voltage voltage provider circuit of the stack, wherein the integrated circuit or an automated test equipment comprising the integrated circuit is configured to set a certain voltage provider circuit of the stack to the fifth configuration, to set an, with regard to the certain voltage provider circuit of the stack, immediately subsequent higher voltage voltage provider circuit to the fourth configuration, and to set an, with regard to the subsequent voltage provider circuit of the stack which is set to the fourth configuration, immediately subsequent higher voltage voltage provider circuit to the third configuration.

According to embodiments of the invention, the first voltage provider circuit, the second voltage provider circuit and the one or more further voltage provider circuits are coupled as a stack, wherein the first, the second and the one or more further voltage provider circuits are structurally and/or functionally identical (e.g. having same sub-circuits; e.g. being configured to provide a same set of functionalities) voltage provider circuits, wherein the integrated circuit or an automated test equipment comprising the integrated circuit is configured (and/or is, for example, adapted) to configure the voltage provider circuits of the stack such that a plurality of successive, e.g. subsequent, voltage provider circuits arranged in the stack provide output voltages in an increasing order, wherein a subsequent circuit stacking connection of a respective voltage provider circuit of the stack is, e.g. configured to be, coupled via an on chip-connection with a previous circuit stacking connection of a respective subsequent higher voltage voltage provider circuit of the stack, wherein the integrated circuit or an automated test equipment comprising the integrated circuit is configured to set a certain voltage provider circuit of the stack to the second configuration, and to set a plurality of, with regard to the certain voltage provider circuit of the stack, subsequent higher voltage voltage provider circuits to the fifth configuration.

According to embodiments of the invention, a respective voltage provider circuit of the stack comprises a respective control unit, wherein a respective control unit is configured to provide a respective analogue control signal based on a digital control, and wherein a respective control unit is configured to provide a respective analogue control signal for regulating a respective voltage based on a potential of a respective power sense input of a respective voltage provider circuit and based on a respective reference signal of a respective voltage provider circuit. Furthermore, a respective voltage provider circuit comprises, e.g. further comprises, a respective differential amplifier, wherein a respective first input, e.g. a positive input, of a respective differential amplifier is coupled with a respective power sense input of a respective voltage provider circuit, wherein a respective second input, e.g. a negative input, of a respective differential amplifier is coupled with a respective reference signal line of a respective voltage provider circuit, and wherein a respective control unit is configured to provide a respective analogue control signal based on an output of a respective differential amplifier. In addition, a respective control unit is configured to digitize an analogue output signal of a respective differential amplifier and to provide a respective analogue control signal based on a digital control of a respective digitized output signal of a respective differential amplifier and a respective voltage provider circuit comprises a respective output unit, wherein a respective output unit is configured to offset a respective analogue control signal or a respective amplified version thereof, based on a respective offset signal of a respective voltage provider circuit, wherein a respective output unit comprises a respective pre-amplifier, a respective adder, a respective output amplifier, and a respective offset signal line and wherein a respective output unit is configured to amplify a respective analogue control signal using a respective pre-amplifier, to offset a respective amplified version of a respective analogue control signal using a respective adder, e.g. using an voltage adder, based on a respective offset signal provided by a respective offset signal line of a respective voltage provider circuit, and to amplify a respective amplified version of the offset amplified analogue control signal using a respective output amplifier in order to provide a respective voltage of a respective voltage provider circuit.

According to embodiments of the invention, the integrated circuit or an automated test equipment comprising the integrated circuit is configured to couple the offset signal line of the voltage provider circuit of the stack which is set to the second configuration with a reference potential, e.g. ground potential, and to uncouple said offset signal line from the reference signal line of said voltage provider circuit (wherein, for example, the integrated circuit is configured to set one or more respective switches such that this functionality is achieved). Furthermore, the integrated circuit or an automated test equipment comprising the integrated circuit is configured to couple the offset signal lines of the voltage provider circuits of the stack which are set to the first configuration with their respective reference signal lines.

According to embodiments of the invention, respective differential amplifiers and respective pre-amplifiers of the voltage provider circuits of the stack are configured to be supplied with a common supply voltage (e.g. a supply voltage within a first common interval, e.g. coupled to a common supply voltage line, e.g. are coupled to a common ground line) and respective output amplifiers of the voltage provider circuits of the stack are configured to be supplied with a further common supply voltage, wherein the further common supply voltage is larger than the common supply voltage with regard to its absolute value (wherein, e.g., the further supply voltage comprises a second common interval, wherein the second interval comprises larger and smaller voltages than the first interval).

According to embodiments of the invention, the integrated circuit or an automated test equipment comprising the integrated circuit is configured to couple a respective offset signal line of a voltage provider circuit of the stack which is set to the fifth or third configuration with a respective reference signal line of the respective voltage provider circuit (wherein, for example, the integrated circuit is configured to set one or more respective switches such that this functionality is achieved) and the integrated circuit or an automated test equipment comprising the integrated circuit is configured to couple the offset signal line of the voltage provider circuit of the stack which is set to the fourth configuration with a reference potential, e.g. a ground potential, and to uncouple said offset signal line from the reference signal line of said voltage provider circuit.

According to embodiments of the invention, respective differential amplifiers and respective pre-amplifiers of the voltage provider circuits of the stack which are set to the fifth and respectively third configuration are configured to be supplied with a common supply voltage (e.g. a supply voltage within a first common interval, e.g. coupled to a common supply voltage line, e.g. are coupled to a common ground line) and the differential amplifier and the pre-amplifier of the voltage provider circuit which is set to the fourth configuration, as well as the output amplifiers of the voltage provider circuits of the stack are configured to be supplied with a further common supply voltage, wherein the further common supply voltage is larger than the common supply voltage with regard to its absolute value (wherein, e.g., the further supply voltage comprises a second common interval, wherein the second interval comprises larger and smaller voltages than the first interval).

According to embodiments of the invention, the integrated circuit or an automated test equipment comprising the integrated circuit is configured to couple a respective offset signal line of a voltage provider circuit of the stack which is set to the fifth configuration with a respective reference signal line of the respective voltage provider circuit (e.g. a supply voltage within a first common interval, wherein, for example, the integrated circuit is configured to set one or more respective switches such that this functionality is achieved) and the integrated circuit or an automated test equipment comprising the integrated circuit is configured to couple the offset signal line of the voltage provider circuit of the stack which is set to the second configuration with a reference potential, e.g. ground potential, and to uncouple said offset signal line from the reference signal line of said voltage provider circuit.

According to embodiments of the invention, respective differential amplifiers and respective pre-amplifiers of the voltage provider circuits which are set to the fifth configuration are configured to be supplied with a common supply voltage (e.g. coupled to a common supply voltage line, e.g. are coupled to a common ground line) and the differential amplifier and the pre-amplifier of the voltage provider circuit which is set to the second configuration, as well as the output amplifiers of the voltage provider circuits of the stack are configured to be supplied with a further common supply voltage, wherein the further common supply voltage is larger than the common supply voltage with regard to its absolute value (wherein, e.g., the further supply voltage comprises a second common interval, wherein the second interval comprises larger and smaller voltages than the first interval).

According to embodiments of the invention, the integrated circuit or an automated test equipment comprising the integrated circuit is configured to configure the reference signal switch, the routing switch and the sense signal switch of the given voltage provider circuit, so that reference signal lines of a preceding voltage provider circuit and of a subsequent voltage provider circuit are coupled while a reference signal line of the given voltage provider circuit is not coupled to the reference signal lines of the preceding voltage provider circuit and of the subsequent voltage provider circuit but coupled to a different potential and such that a potential of the reference signal lines of the preceding voltage provider circuit and of the subsequent voltage provider circuit is determined by the given voltage provider circuit.

According to embodiments of the invention, the integrated circuit or an automated test equipment comprising the integrated circuit is configured to configure the reference signal switch, the routing switch and the sense signal switch of the given voltage provider circuit, so that reference signal lines of a preceding voltage provider circuit, of the given voltage provider circuit and of a subsequent voltage provider circuit are coupled to a potential which is different from a ground potential, and which is provided by yet another voltage provider circuit.

Furthermore, embodiments according to the invention comprise an automated test equipment for testing a device under test, wherein the automated test equipment comprises an integrated circuit according to one or more of the embodiments as disclosed herein, wherein voltage outputs of the voltage provider circuits are coupled with respective device under test connections, and wherein, for example, power sense inputs of the voltage provider circuits are coupled with the respective device under test connections.

Embodiments according to the invention comprise a method for testing a device under test, DUT, comprising providing, with a first voltage provider circuit, a first voltage to the DUT and regulating the first voltage with respect to a first reference signal, which is present on a first reference signal line of the first voltage provider circuit, providing, with a second voltage provider circuit, a second voltage to the DUT and regulating the second voltage with respect to a second reference signal, which is present on a second reference signal line of the second voltage provider circuit and switchably, e.g. selectively, e.g. selectably, coupling the second reference signal line with a first power, e.g. positive, sense input of the first voltage provider circuit via an on-chip connection, for example, via an on-chip switch, such that the second reference signal is determined by a potential of the first power sense input of the first voltage provider circuit.

The method as described above is based on the same considerations as the above-described integrated circuit and/or as the above-described automated test equipment. The method can, by the way, be completed with all features and functionalities, which are also described with regard to the integrated circuit and/or the automated test equipment.

According to embodiments of the invention, the DUT is a battery management system and the first voltage is provided to the DUT in order to simulate a first battery cell of a battery cell stack and the second voltage is provided to the DUT in order to simulate a second battery cell of the battery cell stack.

Furthermore, it is to be noted that embodiments are not limited to battery management systems. Any DUT with a demand for ‘stacked’ topology can, for example, be served with an integrated circuit according to embodiments, for example because the inventive circuit is able to programmatically adopt to the DUT's requirements.

### BRIEF DESCRIPTION OF THE DRAWINGS

The drawings are not necessarily to scale, emphasis instead generally being placed upon illustrating the principles of the invention. In the following description, various embodiments of the invention are described with reference to the following drawings, in which:

FIG. 1 shows a schematic view of an integrated circuit for testing a device under test according to embodiments of the invention;

FIG. 2 shows a schematic view of an integrated circuit with additional, optional features, according to embodiments of the invention;

FIG. 3 shows a schematic view of an integrated circuit with an optional center offset, according to embodiments of the invention;

FIG. 4 shows a schematic view of an integrated circuit with an optional common offset, according to embodiments of the invention;

FIG. 5 shows a schematic view of a voltage provider circuit according to embodiments of the invention;

FIG. 6 shows a schematic block diagram of a method for testing a device under test, according to embodiments of the invention;

FIG. 7 shows a schematic view of an integrated circuit according to a further embodiment of the invention;

FIG. 8 shows a schematic view of a device under test in its intended use case, according to embodiments of the invention;

FIG. 9 shows a schematic view of the device under test with the challenging requirements for this use case according to embodiments;

FIG. 10 shows a schematic view of a traditional approach requiring many independently floating resources of a test system; and

FIG. 11 shows a schematic view of an optional key aspect according to embodiments of the invention.

### DETAILED DESCRIPTION OF THE EMBODIMENTS

Equal or equivalent elements or elements with equal or equivalent functionality are denoted in the following description by equal or equivalent reference numerals even if occurring in different figures.

In the following description, a plurality of details is set forth to provide a more throughout explanation of embodiments of the present invention. However, it will be apparent to those skilled in the art that embodiments of the present invention may be practiced without these specific details. In other instances, well-known structures and devices are shown in block diagram form rather than in detail in order to avoid obscuring embodiments of the present invention. In addition, features of the different embodiments described herein after may be combined with each other, unless specifically noted otherwise.

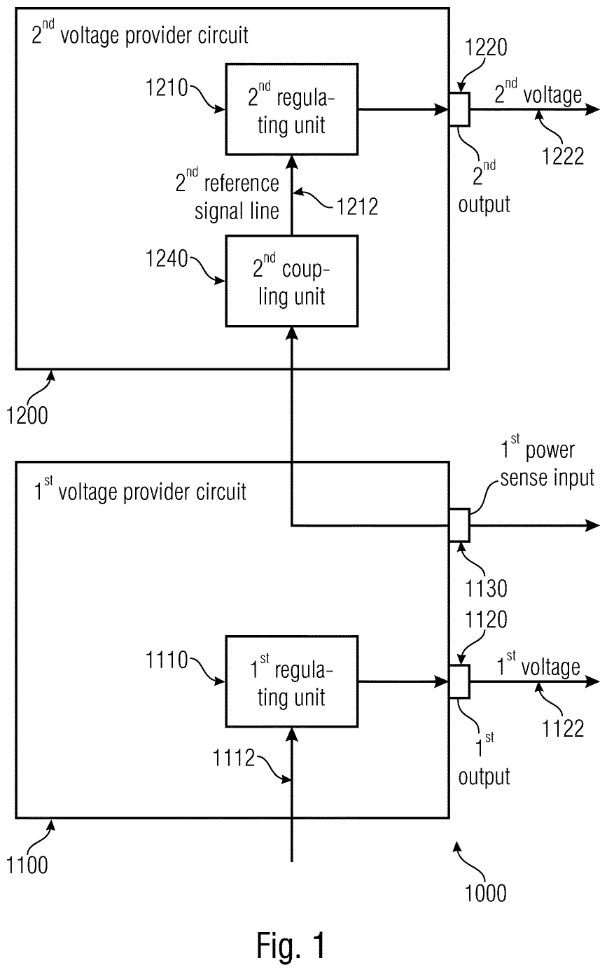

FIG. 1 shows a schematic view of an integrated circuit for testing a device under test according to embodiments of the invention. FIG. 1 shows integrated circuit 1000 comprising a first voltage provider circuit 1100 and a second voltage provider circuit 1200.

The first voltage provider circuit 1100 comprises a first regulating unit 1110, a first output 1120 and a first power sense input 1130. The first voltage provider circuit 1100 is configured to provide a first voltage 1122, as shown as an optional feature via the first output 1120. Furthermore, the first voltage provider circuit 1110 is configured to regulate the first voltage 1120, as shown as an optional feature, using the first regulation unit 1110, with respect to a first reference signal, which is present on a first reference signal line 1112.

The second voltage provider circuit 1200 comprises a second regulating unit 1210, a second output 1220 and a second coupling unit 1240. The second voltage provider circuit 1200 is configured to provide a second voltage 1222, as shown as an optional feature, via the second output 1220. The second voltage provider circuit 1200 is configured to regulate the second voltage 1222, as shown as an optional feature, using the second regulation unit 1210, with respect to a second reference signal, which is present on a second reference signal line 1212. Moreover, the second voltage provider circuit 1200 is configured to switchably couple the second reference signal line 1212 with the first power sense input 1130 of the first voltage provider circuit 1100 via an on-chip connection, using the second coupling unit 1240, such that the second reference signal is determined by a potential of the first power sense input 1130 of the first voltage provider circuit 1100.

As an example, the first power sense input 1130 may be used to measure the first voltage 1122 provided via the first output port 1120. Optionally, (not shown), such a measurement may be provided to the first regulating unit 1110 for the regulation of the first voltage 1122. The measurement of the signal at the first power sense input 1130 is routed on-chip, via the second coupling unit 1240 (e.g. comprising a reference signal switch) to the second regulation unit 1210 (e.g. comprising a control unit, an output unit, a differential amplifier and/or additional switches, e.g. a routing switch and/or a sense signal switch (it is to be noted that the first regulating unit may comprise respective features as well)). For the second regulation unit 1210, the provided signal may be used as an offset signal, to allow for a regulation of the second voltage 1222 in a limited voltage interval, hence allowing to achieve a high accuracy, whilst allowing to provide a voltage with a high absolute value.

It is to be noted that optionally, the second voltage provider circuit 1200 may as well comprise a power sense input, e.g. a second power sense input. The power sense, PS, input may be used inside every single provider for its own purposes, and, optionally additionally be fed to the subsequent voltage provider, (e.g. except, 2nd voltage provider is the last one (topmost)).

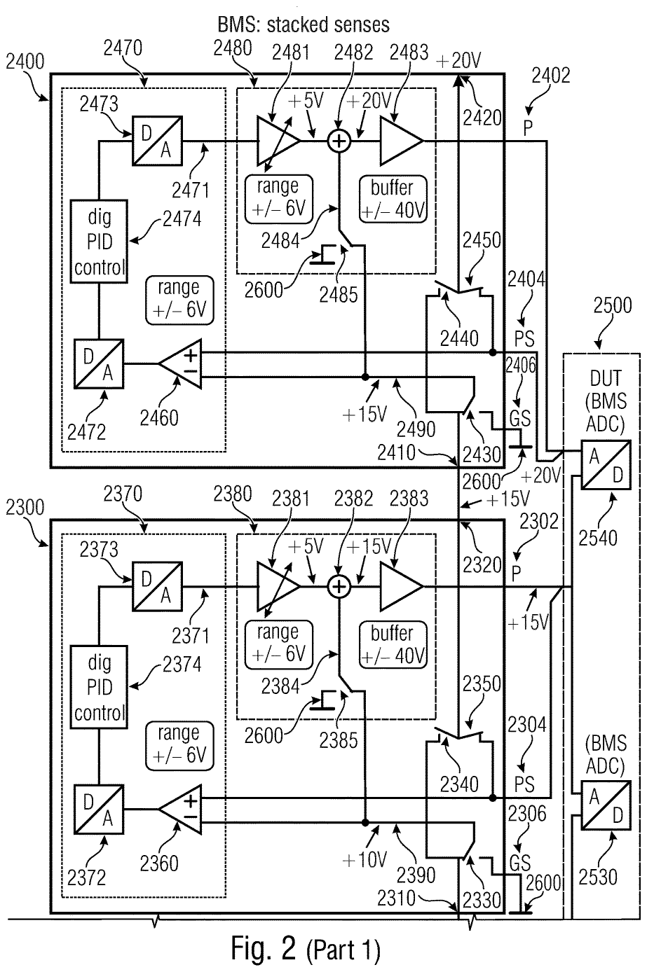

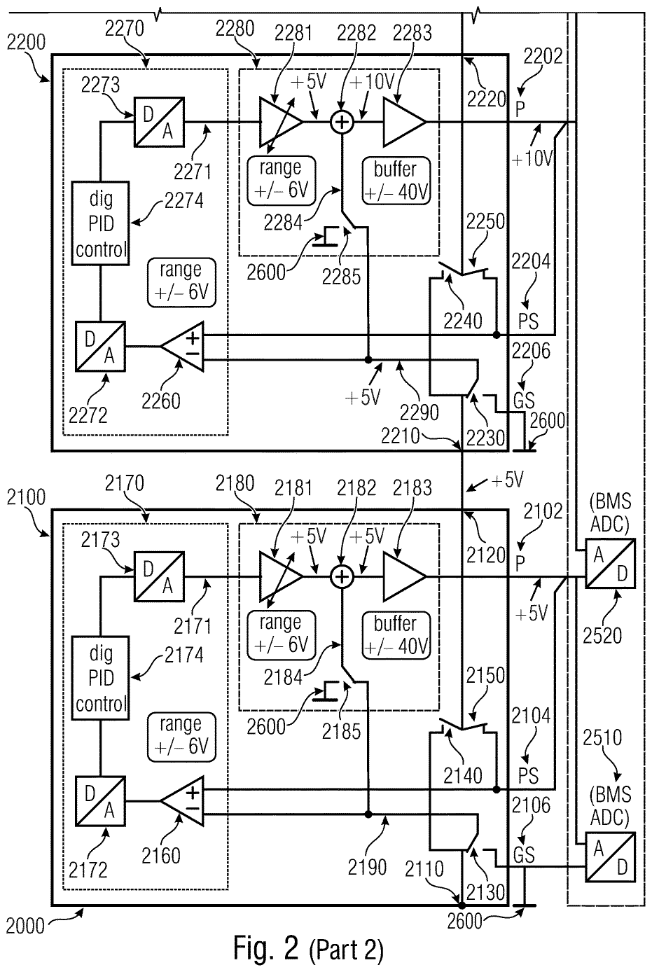

FIG. 2 shows a schematic view of an integrated circuit with additional, optional features, according to embodiments of the invention. FIG. 2 shows integrated circuit 2000 comprising a plurality of voltage provider circuits 2100, 2200, 2300, 2400 for testing a device under test 2500, which is, as an example, a battery management system.

As optional features (individually and in combination), each voltage provider circuit 2x00 (x ϵ {1, 2, 3, 4}) comprises a previous circuit stacking connection 2x10 and a subsequent circuit stacking connection 2x20, a reference signal switch 2x30, a routing switch 2x40, a sense signal switch 2x50, a differential amplifier 2x60, a control unit 2x70 and an output unit 2x80. As shown as an optional feature, a respective control unit 2x70 may comprise a corresponding differential amplifier 2x60, however, said amplifier may as well not be part of the respective control unit 2x70. Furthermore, each voltage provider circuit 2x00 comprises a reference signal line 2x90. Furthermore, as optional features (individually and in combination) each voltage provider circuit 2x00 comprises an output 2x02, a power sense input 2x04 and a ground sense input 2x06. As another optional feature, the device under test 2500 comprises a plurality of sub-devices 2510, 2520, 2530, 2540, here, as an example, in the form of individual ADCs (Analog-to-Digital-Converter), which are arranged in a stacked configuration.

In the example shown in FIG. 2 the device under test 2500 in the form of the battery management system is configured to test a stack of battery cells with the respective ADCs 2510-2540. Hence, in order to test the device under test 2500, the integrated circuit 2000 is configured to simulate a predefined behavior of such a battery cell stack. Therefore, each ADC (e.g. 2530) is coupled with two subsequent outputs (e.g. 2202 and 2302), so that a potential difference between respective voltages provided by the respective voltage provider circuits (e.g. 2200 and 2300) are provided to the ADC to simulate a battery cell. The respective voltage (e.g. via output 2302) provided is measured and controlled using respective power sense inputs (e.g. 2304), which are hence coupled with corresponding outputs (e.g. 2x02 coupled with 2x04). A bottom, e.g. lowest voltage, ADC 2510 is coupled with a ground reference 2600.

Hence, as shown as an optional feature, in FIG. 2, the plurality of voltage provider circuits 2x00 of the integrated circuit 2000 is coupled as a stack in order to provide a plurality of output voltages via outputs 2x02.

For the provision of respective inventive coupling configurations, as optional features (both individually and taken in combination), a respective reference signal switch 2x30 is configured to switchably connect a respective reference signal line 2x90 with a respective previous circuit stacking connection 2x10 and alternatively with a respective ground sense input 2x06, a respective routing switch 2x40 is configured to switchably connect a respective previous circuit stacking connection 2x10 with a respective subsequent circuit stacking connection 2x20 and a respective sense signal switch 2x50 is configured to switchably connect a respective subsequent circuit stacking connection2x20 with a respective power sense input 2x04.

As an optional feature, the integrated circuit 2000 may be configured to switchably couple respective reference signal lines 2x90 with a shared common ground reference line.

For the provision of the plurality of output voltages via outputs 2x02, each of the integrated circuits 2x00 is configured to regulate a respective output voltage using respective control units 2x70 with respect to a respective reference signal, which is present on a respective reference signal line 2x90 and as shown as an example with respect to a potential on a respective power sense input 2x04.

Therefore, a respective control unit 2x70 is configured to provide a respective analogue control signal 2x71 based on a digital control. In order to provide the digital control, as optional features, respective control units 2x70 comprise ADCs (Analog-to-Digital-Converters) 2x72, DACs (Digital-to-Analog-Converters) 2x73 and controllers 2x74. As an example, controllers in the form of digital PID-controllers are shown (other controller types may be used as well). Accordingly, a respective ADC 2x72 is configured to digitize an analogue output signal 2x61 of a respective differential amplifier 2x60 to control the same using a respective controller 2x74 and to provide a respective analogue control signal 2x71 based on a following DAC conversion using a respective DAC 2x73. Hence, a regulation is performed digitally, using a digital control of the digitized output signal of a respective differential amplifier 2x60.

Accordingly, as shown as an optional feature, a first, e.g. positive, input of a respective differential amplifier 2x60 is coupled with a respective power sense input 2x04 of a respective voltage provider circuit 2x00 and a second, e.g. negative, input of a respective differential amplifier 2x60 is coupled with a respective reference signal line 2x90.

As another optional feature, respective differential amplifiers 2x60 are ground referenced, highly linear and insensitive to high offset voltages. In addition, as an optional feature, a respective voltage provider circuit 2x00 is configured to compensate, at least partially, a common mode error of a respective differential amplifier 2x60.

Based on a respective analogue control signal 2x71, a respective output unit 2x80 is offset. As shown as an optional feature, a respective output unit 2x80 may further comprise a pre-amplifier 2x81, an adder 2x82, an output amplifier 2x83, and an offset signal line 2x84. A respective pre-amplifier 2x81 is configured to amplify the first analogue control signal 2x71, a respective adder is configured to offset the amplified version of the analog control signal (or optionally the analog control signal in case no pre-amplifier is present or no amplification is performed) based on an offset signal which is provided by the offset signal line 2x84 and a respective output amplifier 2x83 is configured to amplify the offset amplified analogue control signal (or the offset analogue control signal) in order to provide a respective voltage provided via a respective output 2x02.

As an optional feature, respective amplifiers 2x81 and 2x83 are ground referenced. Furthermore, as another optional feature, a respective output unit 2x80 comprises a respective offset switch 2x85. A respective offset switch 2x85 is configured to couple a respective offset line 2x84 with a respective reference signal line 2x90 via an on-chip connection. Hence, an offset based on a voltage of a preceding voltage provider circuit (e.g. 2200) may be used as an offset for the voltage of a given voltage provider circuit (e.g. 2300). In addition, a respective offset switch 2x85 is configured to couple a respective offset line 2x84 with a ground reference potential 2600, for example, to disable a respective offset functionality of a respective output unit (e.g. 2180). This may allow providing a setup for a simulating a first battery cell of a battery cell stack.

With regard to the supply voltages of the respective amplifiers and voltage levels, it is to be noted that such values are only provided in FIG. 2 for illustration purposes. Embodiments may comprise amplifiers with different supply voltages (e.g. intervals) and voltage levels.

As shown in FIG. 2, according to embodiments of the invention, optionally respective differential amplifiers 2x60 and respective pre-amplifiers 2x81 may comprise a common supply voltage interval, or even a common supply voltage, hence allowing for a simple amplifier supply within the integrated circuit. As an example respective output amplifiers 2x83 may as well have a common, but for example higher voltage, supply voltage.

Furthermore, as shown, respective voltage provider circuits 2x00 may be structurally and/or functionally identical or equal or at least similar. However, the setup shown in FIG. 2 is to be understood as an example according to an embodiment. Hence, individual voltage provider circuits may deviate in their respective structure (e.g. not comprising necessarily the same optional features as other voltage provider circuits of the respective integrated circuit).

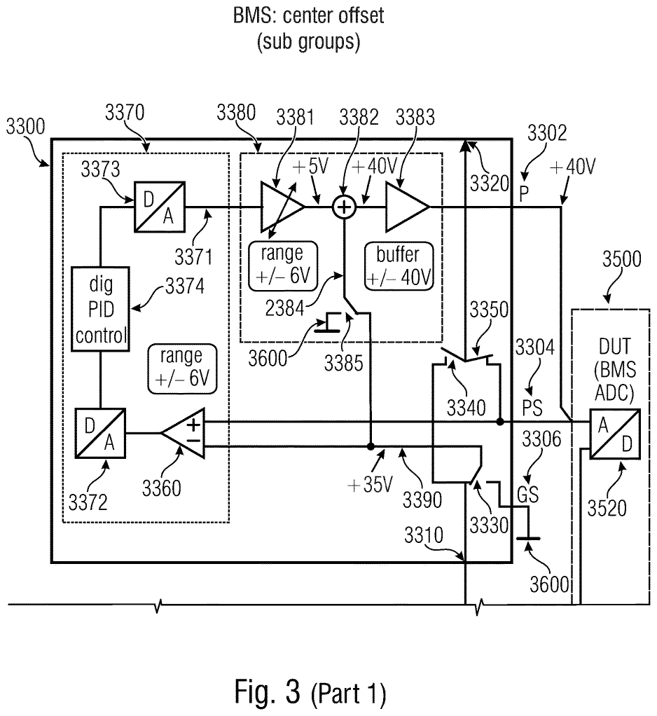

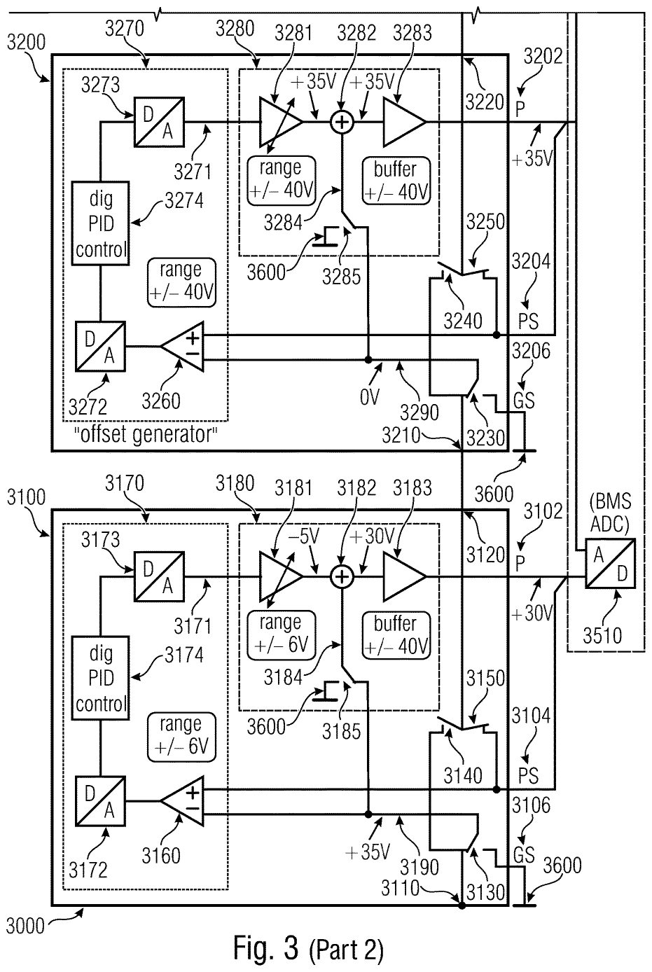

FIG. 3 shows a schematic view of an integrated circuit with an optional center offset, according to embodiments of the invention. FIG. 3 shows integrated circuit 3000 comprising a plurality of voltage provider circuits 3100, 3200, 3300 for testing a device under test 3500, which is, as an example, a battery management system. For the sake of brevity, it is to be noted that elements as discussed in the context of FIG. 3 may have same, equal or corresponding functionalities as corresponding elements in FIG. 2. In particular, it is to be noted that elements 3abc (e.g. 3300) as discussed in the context of FIG. 3 may have same, equal or corresponding functionalities as corresponding elements 2abc (e.g. 2300) in FIG. 2.

In contrast to integrated circuit 2000, integrated circuit 3000 comprises a voltage provider 3200, which acts as a center offset. Therefore, a configuration of voltage provider circuit 3200 is set, so as to couple its power sense input 3204 to the reference signal line 3390 of the subsequent voltage provider circuit 3300 via an on-chip connection and to the reference signal line 3190 of the preceding voltage provider circuit 3100 via an on-chip connection.

For the offset functionality, as an additional optional feature, the amplifiers 3281, 3281 and 3260 are all provided with the higher voltage supply voltage, wherein in the specific example of circuit 3000, the amplifiers have a same supply voltage or at least supply voltage interval.

Hence, as shown in FIG. 3, a respective voltage provider circuit (e.g. 3200) may optionally establish a route between a reference signal line 3190 of a preceding voltage provider circuit and a reference signal line 3390 of a subsequent reference signal line.

As shown in FIG. 3 one use case addressed with embodiments according to the invention is a testing performed for a stack of ADCs (e.g. of a battery management systems, BMS e.g. 3500), which is divided in smaller groups of adjacent ADCs. As shown, a smallest unit may comprise two ADCs, 3510, 3520, which are connected to each other at their center. The integrated circuit 3000 as shown may allow the testing of such a setup.

Furthermore, with regard to FIG. 3 it is to be noted that respective voltage provider circuits may be configured to be set in different states. As shown with voltage provider circuits 3100 and 3300, in a first state, respective power sense inputs may be coupled to one out of a reference signal line of a preceding voltage provider circuit and a reference signal line of a subsequent voltage provider circuit. As shown with voltage provider circuit 3200, in a second state a respective power sense input may be coupled to both the reference signal line of the preceding voltage provider circuit and the reference signal line of the subsequent voltage provider circuit, such that reference signals of the preceding voltage provider circuit and of the subsequent voltage provider circuit are determined by a potential at the power sense input of the voltage provider circuit 3200.

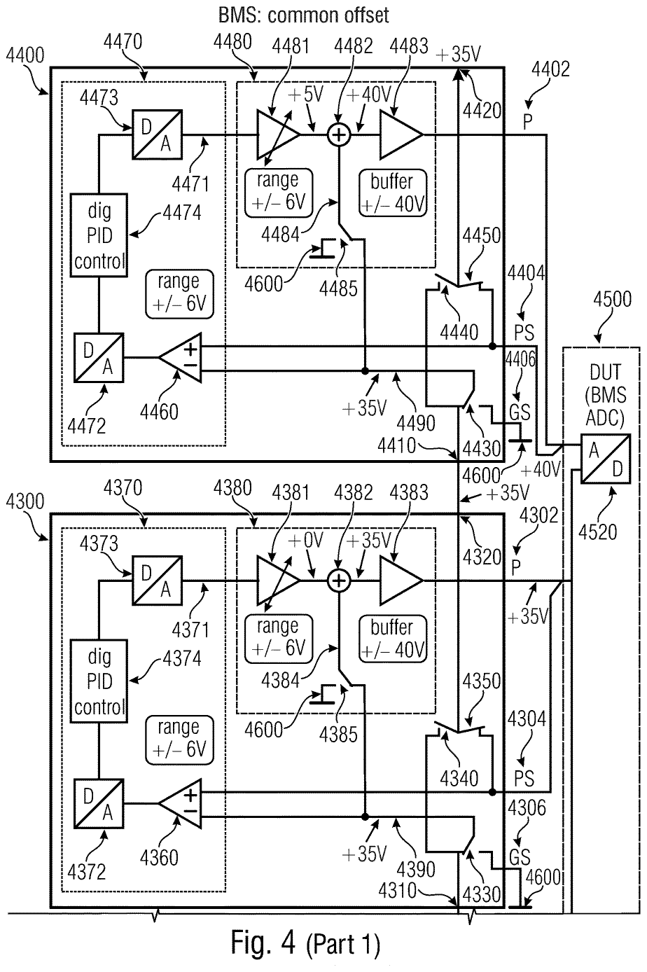

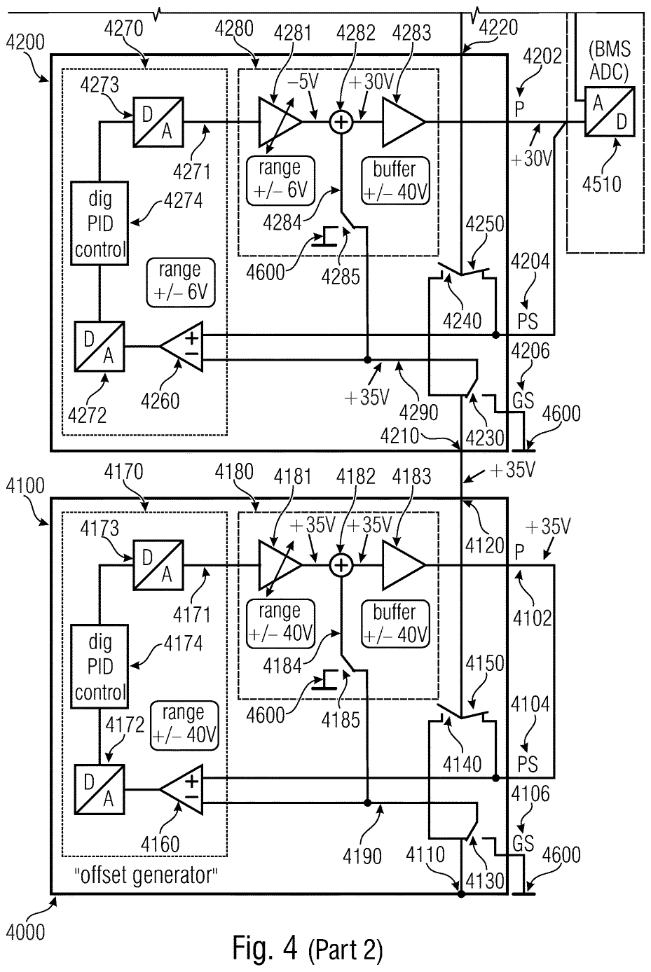

FIG. 4 shows a schematic view of an integrated circuit with an optional common offset, according to embodiments of the invention. FIG. 4 shows integrated circuit 4000 comprising a plurality of voltage provider circuits 4100, 4200, 4300, 4400 for testing a device under test 4500, which is, as an example, a battery management system. For the sake of brevity, it is to be noted that elements as discussed in the context of FIG. 4 may have same, equal or corresponding functionalities as corresponding elements in FIGS. 3 and/or 2. In particular, it is to be noted that elements 4abc (e.g. 4300) as discussed in the context of FIG. 4 may have same, equal or corresponding functionalities as corresponding elements 2abc (e.g. 2300) in FIG. 2 and/or elements 3abc (e.g. 3300) as discussed in the context of FIG. 3.

As an optional feature, in the configuration shown, voltage provider circuit 4100 may act as a common offset for all subsequent voltage provider circuits 4200, 4300, 4400. It is to be noted that a routing from output 4104 to power sense input 4104 may optionally be an on-chip connection.

Furthermore, according to embodiments of the invention, an integrated circuit, e.g. 2000, 3000, 4000, or an automated test equipment comprising the integrated circuit may optionally be configured to set a given voltage provider circuit to a predefined configuration by controlling a respective reference signal switch, a respective routing switch and a respective sense signal switch of the given voltage provider circuit. As an example, different configurations of voltage provider circuits are shown in FIGS. 2-4.

As an example, in a first configuration (e.g. as shown with voltage provider circuits 2200, 2300, 2400), for a given voltage provider circuit (e.g. 2300), the reference signal line (e.g. 2390) is connected with the previous circuit stacking connection (e.g. 2310), the reference signal line (e.g. 2390) is unconnected with a ground sense input (e.g. 2306), the previous circuit stacking connection (e.g. 2310) is unconnected with the subsequent circuit stacking connection (e.g. 2320), and the power sense input (e.g. 2304) is connected with the subsequent circuit stacking connection (e.g. 2320).

As an example, in a second configuration (e.g. as shown with voltage provider circuits 2100, 4100), for a given voltage provider circuit (e.g. 2100), the reference signal line (e.g. 2190) is unconnected with the previous circuit stacking connection (e.g. 2110), the reference signal line (e.g. 2190) is connected with a ground sense input (e.g. 2130), the previous circuit stacking connection (e.g. 2110) is unconnected with the subsequent circuit stacking connection (e.g. 2120) and the power sense input (e.g. 2104) is connected with the subsequent circuit stacking connection (e.g. 2120).

It is to be noted that voltage provider circuit 4100 may, for example, be in a different sub-configuration compared to voltage provider circuit 4100 wherein an output 4102 is coupled with a power sense input 4104 instead of a coupling with the DUT. However, according to some embodiments voltage provider circuits 2100 and 4100 may as well be considered to be in different configurations. In particular, it is to be noted that the connection between output 4102 and input 4104 may be implemented on-chip or via an external connection.

As an example, in a third configuration (e.g. as shown with voltage provider circuit 3300), for a given voltage provider circuit (e.g. 3300), the reference signal line (e.g. 3390) is connected with the previous circuit stacking connection (e.g. 3310), the reference signal line (e.g. 3390) is unconnected with a ground sense input (e.g. 3306), the previous circuit stacking connection (e.g. 3310) is unconnected with the subsequent circuit stacking connection (e.g. 3320) and the power sense input (e.g. 3304) is unconnected with the subsequent circuit stacking connection (e.g. 3320).

As an example, in a fourth configuration (e.g. as shown with voltage provider circuit 3200), for a given voltage provider circuit (e.g. 3200), the reference signal line (e.g. 3290) is unconnected with the previous circuit stacking connection (e.g. 3210), the reference signal line (e.g. 3290) is connected with a ground sense input (e.g. 3206), the previous circuit stacking connection (e.g. 3210) is connected with the subsequent circuit stacking connection (e.g. 3220) and the power sense input (e.g. 3204) is connected with the subsequent circuit stacking connection (e.g. 3220) of the given voltage provider circuit. This may allow providing a center offset functionality.

As an example, in a fourth configuration (e.g. as shown with voltage provider circuits 3100, 4200, 4300, 4400), for a given voltage provider circuit (e.g. 4300), the reference signal line (e.g. 4390) is connected with the previous circuit stacking connection (e.g. 4310), the reference signal line (e.g. 4390) is unconnected with a ground sense input (e.g. 4306), the previous circuit stacking connection (e.g. 4310) is connected with the subsequent circuit stacking connection (e.g. 4320), and the power sense input (e.g. 4304) is unconnected with the subsequent circuit stacking connection (e.g. 4320).

Hence, as an example, according to the embodiment as shown in FIG. 2, the voltage provider circuits of the integrated circuit are, as an optional feature, coupled as a stack via on-chip connections and, as another optional feature, structurally identical. Furthermore, as an example, successive voltage provider circuits (2100->2200->2300->2300) arranged in the stack provide output voltages in an increasing order (5V->10V->15V->20V). This is achieved by setting a certain (e.g. first, e.g. lowest output voltage) voltage provider circuit (e.g. 2100) of the stack to the second configuration, and by setting the plurality of, with regard to the certain voltage provider circuit of the stack, immediately subsequent higher voltage voltage provider circuits (e.g. 2200, 2300, 2400) to the first configuration.

Furthermore, as shown in FIG. 2, as an optional feature, the integrated circuit 2000 is configured to couple the offset signal line (e.g. 2184) of the voltage provider circuit (e.g. 2100) of the stack, which is set to the second configuration with a reference potential (e.g. 2600) and to uncouple said offset signal line from the reference signal line (e.g. 2190) of said voltage provider circuit. In addition, as shown as an optional feature, the integrated circuit 2000 is configured to couple the offset signal lines (e.g. 2284, 2384, 2484) of the voltage provider circuits of the stack, which are set to the first configuration with their respective reference signal lines (e.g. 2290, 2390, 2490).

As shown in the example of FIG. 2, in such a configuration, respective differential amplifiers (e.g. 2x60) and respective pre-amplifiers (e.g. 2x81) of the voltage provider circuits of the stack may be supplied with a common supply voltage, whilst respective output amplifiers (e.g. 2x83) of the voltage provider circuits of the stack may be supplied with a further common supply voltage, which is larger than the common supply voltage with regard to its absolute value.

Hence, as another example, according to the embodiment as shown in FIG. 3, the voltage provider circuits of the integrated circuit are, as an optional feature, coupled as a stack via on-chip connections and, as another optional feature, structurally identical. Furthermore, as an example, successive voltage provider circuits (3100->3200->3300) arranged in the stack provide output voltages in an increasing order (30V->35V->40V). This is achieved by setting a certain (e.g. first, e.g. lowest output voltage) voltage provider circuit (e.g. 3100) of the stack to the fifth configuration, by setting a, with regard to the certain voltage provider circuit of the stack, immediately subsequent higher voltage voltage provider circuit (e.g. 3200) to the fourth configuration (which may act as a center offset for the provided voltages), and by setting a, with regard to the subsequent voltage provider circuit of the stack which is set to the fourth configuration, immediately subsequent higher voltage voltage provider circuit (e.g. 3300) to the third configuration.

Furthermore, as shown in FIG. 3, as an optional feature, the integrated circuit 3000 is configured to couple a respective offset signal line (e.g. 3184, 3384) of a voltage provider circuit of the stack which is set to the fifth or third configuration with a respective reference signal line (e.g. 3190, 3390) of the respective voltage provider circuit, to couple the offset signal line (e.g. 3284) of the voltage provider circuit of the stack which is set to the fourth configuration with a reference potential (e.g. 3600), and to uncouple said offset signal line from the reference signal line (e.g. 3290) of said voltage provider circuit.

As shown in the example of FIG. 3, in such a configuration, respective differential amplifiers (e.g. 3160, 3360) and respective pre-amplifiers (e.g. 3181, 3381) of the voltage provider circuits of the stack which are set to the fifth and respectively third configuration may be supplied with a common supply voltage, whilst, the differential amplifier (e.g. 3260) and the pre-amplifier (e.g. 3281) of the voltage provider circuit which is set to the fourth configuration, as well as the output amplifiers (e.g. 3183, 3283, 3383) of the voltage provider circuits of the stack may be supplied with a further common supply voltage, wherein the further common supply voltage is larger than the common supply voltage with regard to its absolute value.

Hence, as another example, according to the embodiment as shown in FIG. 4, the voltage provider circuits of the integrated circuit are, as an optional feature, coupled as a stack via on-chip connections and, as another optional feature, structurally identical. Furthermore, as an example, successive voltage provider circuits (4200->4300->4400) arranged in the stack provide output voltages in an increasing order (30V->35->40V). This is achieved by setting a certain (e.g. first, e.g. lowest output voltage) voltage provider circuit (e.g. 4100) of the stack to the second configuration, and by setting the plurality of, with regard to the certain voltage provider circuit of the stack, subsequent higher voltage voltage provider circuits (e.g. 4200, 4300, 4400) to the fifth configuration.

Furthermore, as shown in FIG. 4, as an optional feature, the integrated circuit 4000 is configured to couple a respective offset signal line (e.g. 4284, 4384, 4484) of a voltage provider circuit of the stack which is set to the fifth configuration with a respective reference signal line (e.g. 4290, 4390, 4490) of the respective voltage provider circuit and to couple the offset signal line (e.g. 4184) of the voltage provider circuit of the stack which is set to the second configuration with a reference potential (e.g. 4600), and to uncouple said offset signal line from the reference signal line (e.g. 4190) of said voltage provider circuit.

As shown in the example of FIG. 4, in such a configuration, respective differential amplifiers (e.g. 4260, 4360, 4460) and respective pre-amplifiers (e.g. 4281, 4381, 4481) of the voltage provider circuits which are set to the fifth configuration may be supplied with a common supply voltage and the differential amplifier (e.g. 4160) and the pre-amplifier (e.g. 4181) of the voltage provider circuit which is set to the second configuration, as well as the output amplifiers (e.g. 4183, 4283, 4383, 4483) of the voltage provider circuits of the stack may be supplied with a further common supply voltage, wherein the further common supply voltage is larger than the common supply voltage with regard to its absolute value.

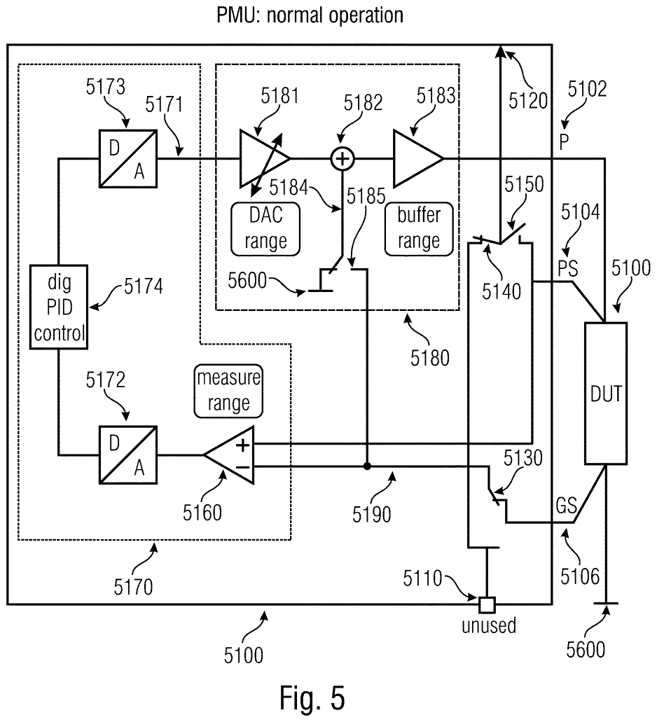

FIG. 5 shows a schematic view of a voltage provider circuit according to embodiments of the invention. For the sake of brevity, it is to be noted that elements 5abc (e.g. 5100) as discussed in the context of FIG. 5 may have same, equal or corresponding functionalities as corresponding elements 4abc (e.g. 4100) in FIG. 4 and/or elements 3abc (e.g. 3100) as discussed in the context of FIG. 3 and/or elements 2abc (e.g. 2100) as discussed in the context of FIG. 2.

FIG. 5 shows an example for the usage of a voltage provider circuit for the testing of a DUT 5100. Accordingly, integrated circuits 2000, 3000 and 4000 may be configured so that respective voltage provider circuits may act as separate, e.g. uncoupled, voltage providers, for the testing of a plurality of separate DUTs in parallel. Hence, integrated circuits may provide a good flexibility for the testing of devices, e.g. devices to be tested in a stacked or separate configuration.

As an example, FIG. 5 may show a PMU (Parametric Measurement Unit) in normal operation. The Parametric Measurement Unit may have one or more of the following functionalities: force programmed current and measure voltage; force programmed voltage and measure current. Furthermore, many more parameters may be programmable; for example slew rate, current and/or voltage clamps, measure ranges, force ranges, . . . . A single channel according to embodiments in ‘normal’ operation may, for example, mainly be a PMU. Furthermore, as an example, a tester card, e.g. in the form of an inventive integrated circuit may consist of up to 128, e.g. identical, Mixed-signal-ASIC-based channels. Reconfiguration of the Mixed-signal-ASICs according to embodiments can achieve different modes required during the test flow, e.g. as discussed in the context of FIGS. 2 to 4. FIG. 5 may hence show the topology of one Mixed-signal-ASIC (e.g. a voltage provider circuit according to embodiments), configured for normal operation.

Referring to FIG. 2, it is to be noted that according to embodiments, a challenge for testing BMS devices may be the wide voltage range overall and the required precision during the test of the devices' ADCs. To solve the problem, for example all measurements (measurements may actually define force accuracy in a digital feedback loop, like Mixed-signal-ASIC) may, for example, need to be done (or are preferably done) in lowest-possible range. In case of BMS cell voltages (e.g. Lithium technology) the best-suited measure range may, for example, be +/−6V. The force buffer (e.g. output amplifier, e.g. output buffer), however, must be or may be capable to cover the full voltage range of the battery stack. As an example, in case of a stack of 24 cells the maximum voltage may be around 24×5V (e.g. 24 times an overcharged cell)->120V. The analog voltage adder may allow using high resolution DACs with low range in the force path. Hence, in other words, mixed-signal-ASICs, configured to test such a stack, may be implemented according to FIG. 2, showing as an example, a testing of a BMS with stacked senses.

Referring to FIG. 3, it is to be noted that recently, it turned out, some vendors of BMS devices, like to test their ADCs in different conditions. One of them may be, to divide the stack in smaller groups of adjacent ADCs. The smallest unit may comprise or even consists of two ADCs, connected to each other at their center. A mixed-signal-ASIC according to embodiments may be configured to support accurate test of such units, e.g. as shown in FIG. 3 showing, as an example, a testing of a BMS with center offset (sub groups).

Referring to FIG. 4, it is to be noted, that in some cases, there may be a requirement to have one extra channel, which may be responsible for the offset of many channels, a mixed-signal-ASIC according to embodiments may be configured as such shown in FIG. 4, showing, as an example, a test of a BMS with common offset.

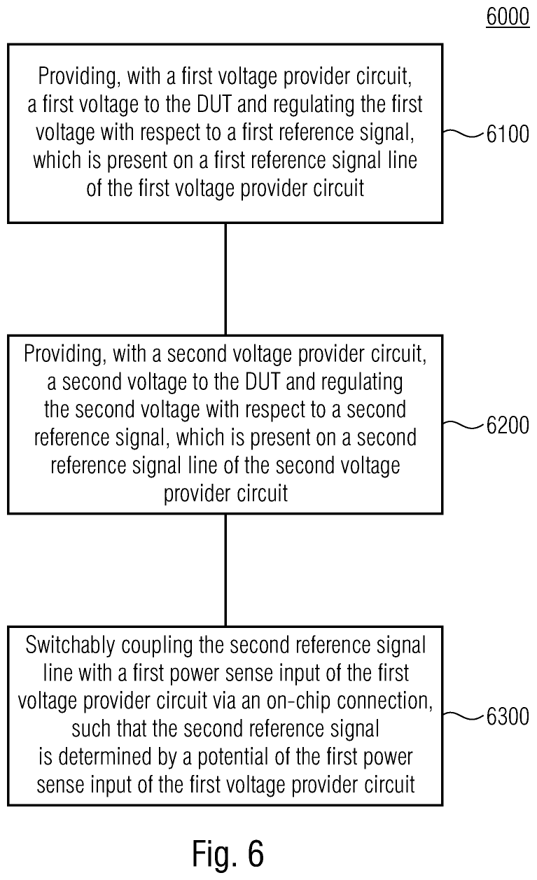

FIG. 6 shows a schematic block diagram of a method for testing a device under test, DUT, according to embodiments of the invention. The method 6000 comprises providing, 6100, with a first voltage provider circuit, a first voltage to the DUT and regulating the first voltage with respect to a first reference signal, which is present on a first reference signal line of the first voltage provider circuit, providing, 6200, with a second voltage provider circuit, a second voltage to the DUT and regulating the second voltage with respect to a second reference signal, which is present on a second reference signal line of the second voltage provider circuit, and switchably coupling, 6300, the second reference signal line with a first power sense input of the first voltage provider circuit via an on-chip connection, such that the second reference signal is determined by a potential of the first power sense input of the first voltage provider circuit.

In the following, embodiments of the invention are further discussed.

Embodiments may achieve the following: Economic approach to meet high precision together with high voltage requirements; Break down accuracy requirements of high voltage applications by adopting test architecture to device architecture; Save loadboard space and components by integration into ASIC; Reduce test cell cost by eliminating costly external DMM.

Furthermore, it is to be noted that a proposed solution according to embodiments may comprise, inter alia: Adopting the test system architecture to device requirements.

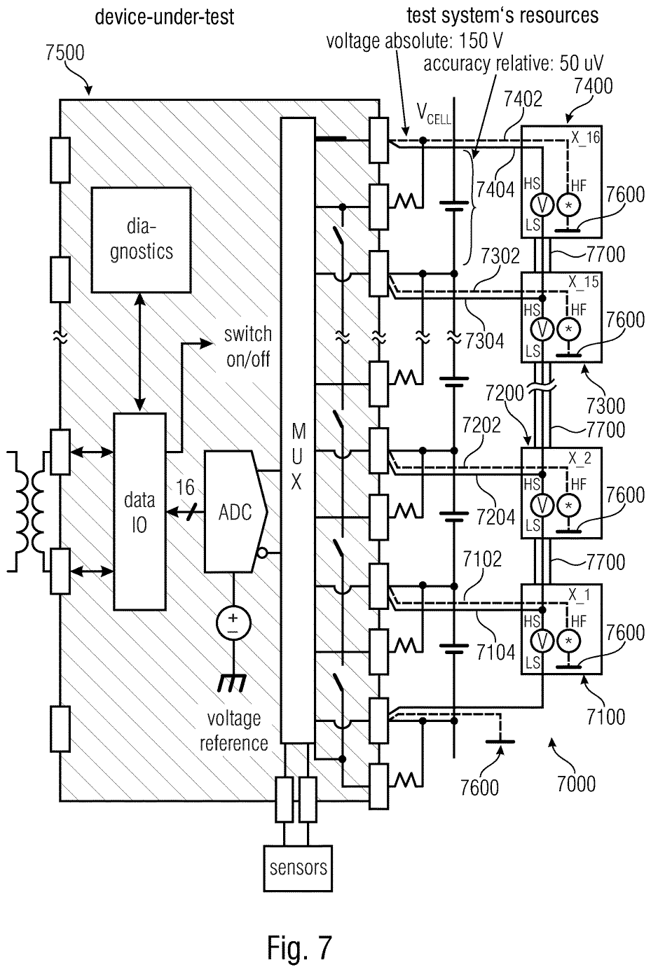

FIG. 7 shows a schematic view of an integrated circuit according to a further embodiment of the invention. FIG. 7 shows integrated circuit 7000 comprising a stack of voltage provider circuits 7x00 which is coupled with a DUT 7500. For the sake of brevity, it is to be noted that elements 7abc (e.g. 7100) as discussed in the context of FIG. 7 may have same, equal or corresponding functionalities as corresponding elements 5abc (e.g. 5100) in FIG. 5 and/or elements 4abc (e.g. 4100) in FIG. 4 and/or elements 3abc (e.g. 3100) as discussed in the context of FIG. 3 and/or elements 2abc (e.g. 2100) as discussed in the context of FIG. 2.

As an example, as shown, the integrated circuit may provide a plurality of output voltages 7x02 to different pins or sub-devices of the DUT, e.g. of a plurality of ADCs. As an example, an output 7402 may achieve an absolute voltage of 150V. However, as explained before, even such a high voltage may be provided with good accuracy, for example with a relative accuracy of 50 uV, e.g. 50 uV. For controlling the voltages, respective voltage provider circuits are configured to perform measurements using power sense inputs 7x04. As shown the coupling as a stack is provided via on-chip connections 7700, for example, via previous circuit stacking connections and via subsequent circuit stacking connection of the respective voltage provider circuits.

It is to be noted that embodiments according to the invention may be solving some or even all of these shortcomings:
Bring accuracy to the point, where it is required or advantageous: Relative accuracy vs. Absolute accuracy
The testsystem's VI sources may be GND-referenced->low cost, higher density (e.g. amplifiers xy83, x, y ϵ {1, 2, 3, 4, 5})
For example, every channel's GND-sense input allows high common mode->high force range may be decoupled from small measurement range, higher measurement precision, lower drift, no shared resource
The expensive high voltage matrix may be included inside an ASIC of the test system (as an example, in other words inside the integrated circuit) and may therefore keep recurring test investments on hardware to a minimum (e.g. switches xy30, xy40 and/or xy50)
External precision DMM may, for example, only required to support spot calibration, or, may, for example, be not required at all, e.g. when the test system's accuracy is adequate.

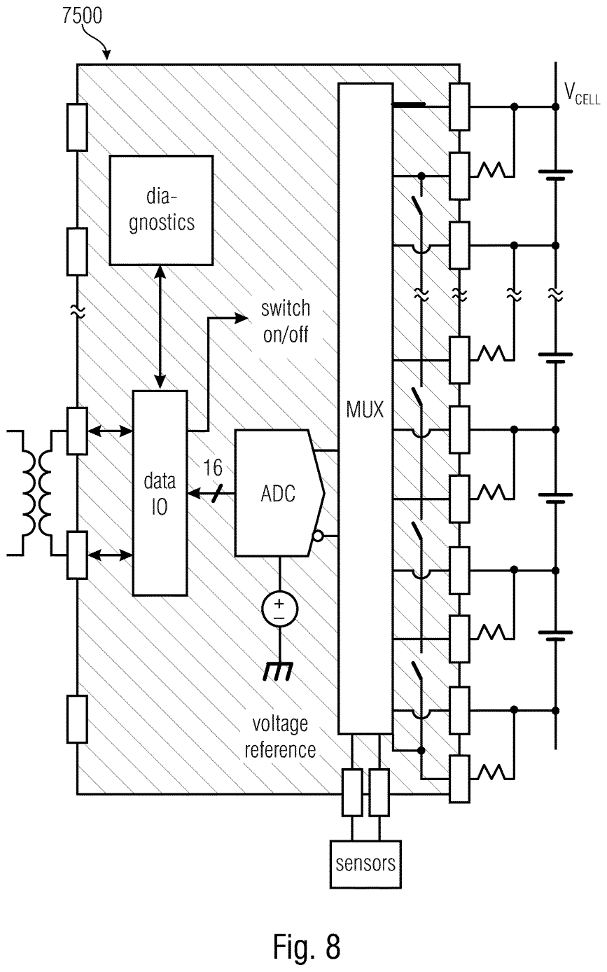

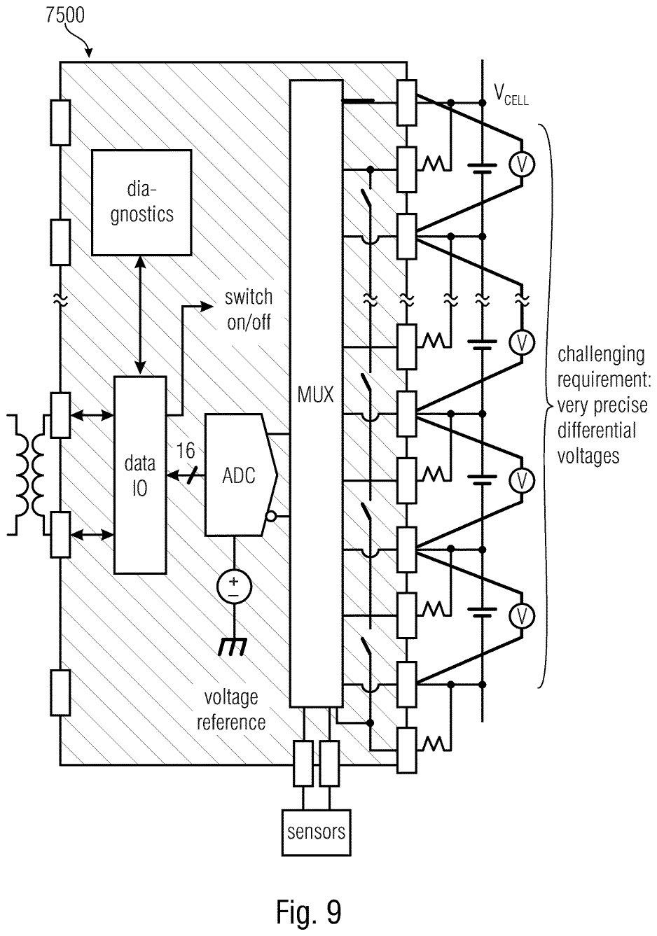

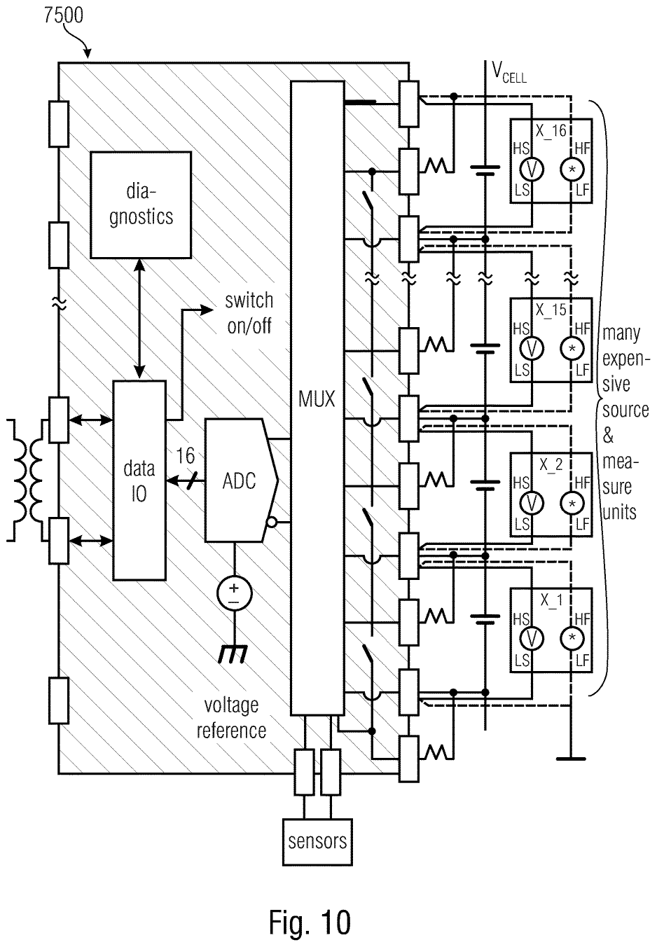

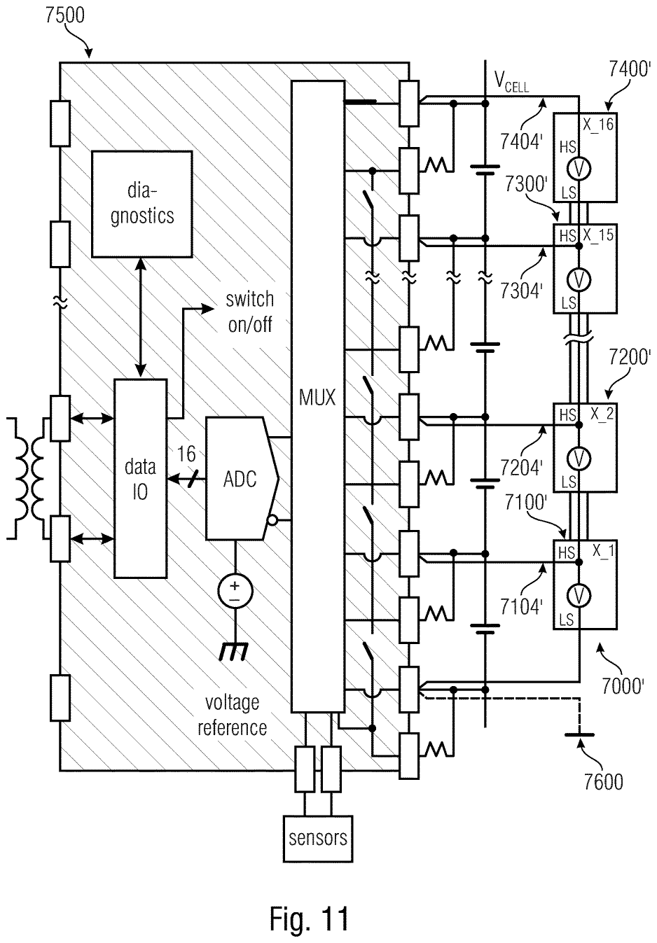

FIG. 8 shows a schematic view of a device under test in its intended use case, according to embodiments of the invention. FIG. 9 shows a schematic view of the device under test with the challenging requirements for this use case: Very precise differential voltages. FIG. 10 shows a schematic view of a traditional approach requiring many independently floating resources of a test system. FIG. 11 shows a schematic view of an optional key aspect according to embodiments of the invention: configurable connections allowing differential measurements. Based on the setup, e.g. comprising integrated circuit 7000′ having circuits 7x00′ with power sense inputs 7x04′, shown in FIG. 11, e.g. in a final step, ground-referenced sources may be able to force precisely regulated voltages, because their measurement units may be operating ‘differentially’ (accuracy is dominated by the measurement units; =>the force units are part of the control loop). This may hence result in the integrated circuit and corresponding setup as shown in FIG. 7.

To put it in other words, with regard to problems addressed or solved by embodiments: Certain test applications may need high differential accuracy, which may be biased by high offset voltages (see e.g. FIGS. 8 and 9). The, for example, typical use case may involve floating voltage sources and/or floating measurement units (see e.g. FIG. 10). These are comparably expensive resources in a test system. Embodiments allow the use of, as an example relatively low cost GND-referenced, units, which can be programmed in a mode with high resolution differential measurement. Accuracy and stability may be significantly enhanced while still allowing to reconfigure each channel in the traditional operation mode.

Hence, as explained before, advantages according to embodiments may comprise any or all of the following: higher density of instruments per available space, lower manufacturing cost, lower test cost for the customer, for example, because of saved components on the load board and optionally saved precision calibration equipment for focus calibration during test.

Therefore, according to embodiments, a programmable configuration may be implemented inside an ASIC, for example, involving digital control loops, which may be able to translate low voltage high precision to high voltage and high differential precision.

Furthermore, a value of embodiments, e.g. a value of a Mixed-signal-ASIC according to embodiments is the configurability of the ASIC to the specific test needs and, of course, the ability to match high precision and wide voltage range.

Furthermore, embodiments according to the invention may perform or comprise aspects of calibration/compensation of common-mode errors and other non-linearities. Embodiments may, for example, make heavy use of those techniques. However, it is to be noted that in this regard, embodiments may optionally make use of conventional techniques for such tasks.

Furthermore, with regard to technical advantages according to embodiments, one or more of the following may be achieved:
Reduced wiring effort on the customers' load boards to attach their devices-under-test, for example, by close to 50% for Battery Management Controllers and similar devices
Moving a, for example huge, number of precision switches, required, as an optional feature, to configure our test equipment individually per channel, into ASICs, may, for example be one of the or even the “key enabler”
Providing the required precision of voltage accuracy biased by quite high offset voltage levels had, for example, been made possible by these technical details:
   1) A highly linear differential amplifier is able to measure high resolution independent of high offset voltage potentials
   2) Digital Control Loop is able to transform the precisely measured voltage to adequate voltage force accuracy with effectively no loss of precision
   3) Achieving such extreme force-precision may be solved by combining the ‘unprecise analog’ voltage feedback with the correction of remaining errors by the digital control loop
Embodiments comprise implementations of well-controlled connection sequences in order to avoid unwanted voltage glitches and current spikes during connections to ‘active’ devices-under-test

Although some aspects have been described in the context of an apparatus, it is clear that these aspects also represent a description of the corresponding method, where a block or device corresponds to a method step or a feature of a method step. Analogously, aspects described in the context of a method step also represent a description of a corresponding block or item or feature of a corresponding apparatus.

Depending on certain implementation requirements, embodiments of the invention can be implemented in hardware or in software. The implementation can be performed using a digital storage medium, for example a floppy disk, a DVD, a CD, a ROM, a PROM, an EPROM, an EEPROM or a FLASH memory, having electronically readable control signals stored thereon, which cooperate (or are capable of cooperating) with a programmable computer system such that the respective method is performed.

Some embodiments according to the invention comprise a data carrier having electronically readable control signals, which are capable of cooperating with a programmable computer system, such that one of the methods described herein is performed.

Generally, embodiments of the present invention can be implemented as a computer program product with a program code, the program code being operative for performing one of the methods when the computer program product runs on a computer. The program code may for example be stored on a machine-readable carrier.

Other embodiments comprise the computer program for performing one of the methods described herein, stored on a machine-readable carrier.

In other words, an embodiment of the inventive method is, therefore, a computer program having a program code for performing one of the methods described herein, when the computer program runs on a computer.

A further embodiment of the inventive methods is, therefore, a data carrier (or a digital storage medium, or a computer-readable medium) comprising, recorded thereon, the computer program for performing one of the methods described herein.

A further embodiment of the inventive method is, therefore, a data stream or a sequence of signals representing the computer program for performing one of the methods described herein. The data stream or the sequence of signals may, for example, be configured to be transferred via a data communication connection, for example via the Internet.

A further embodiment comprises a processing means, for example a computer, or a programmable logic device, configured to or adapted to perform one of the methods described herein.

A further embodiment comprises a computer having installed thereon the computer program for performing one of the methods described herein.

In some embodiments, a programmable logic device (for example a field programmable gate array) may be used to perform some or all of the functionalities of the methods described herein. In some embodiments, a field programmable gate array may cooperate with a microprocessor in order to perform one of the methods described herein. Generally, the methods are preferably performed by any hardware apparatus.

The above-described embodiments are merely illustrative for the principles of the present invention. It is understood that modifications and variations of the arrangements and the details described herein will be apparent to others skilled in the art. It is the intent, therefore, to be limited only by the scope of the impending patent claims and not by the specific details presented by way of description and explanation of the embodiments herein.

1. An integrated circuit for testing a device under test comprising:
a first voltage provider circuit configured to provide a first voltage; and
a second voltage provider circuit configured to provide a second voltage;
wherein the first voltage provider circuit is configured to regulate the first voltage with respect to a first reference signal, on a first reference signal line;
wherein the second voltage provider circuit is configured to regulate the second voltage with respect to a second reference signal, on a second reference signal line; and
wherein the second voltage provider circuit is configured to switchably couple the second reference signal line with a first power sense input of the first voltage provider circuit via an on-chip connection, the second reference signal being determined by a potential of the first power sense input of the first voltage provider circuit.

2. The integrated circuit according to claim 1, wherein the first voltage provider circuit is configured to switchably couple the second reference signal line with the first power sense input of the first voltage provider circuit via an on-chip connection, the second reference signal being determined by a potential of the first power sense input of the first voltage provider circuit.

3. The integrated circuit according to claim 1,
wherein the first voltage provider circuit is further configured to switchably couple the first reference signal line, via an on-chip connection, with a first ground sense input of the first voltage provider circuit; or
wherein the second voltage provider circuit is further configured to switchably couple the second reference signal line, via an on-chip connection, with a second ground sense input of the second voltage provider circuit.

4. The integrated circuit according to claim 3, wherein the first voltage provider circuit and the second voltage provider circuit are configured to switchably couple respective reference signal lines with a shared common ground reference line of the integrated circuit.

5. The integrated circuit according to claim 1, wherein the first voltage provider circuit or the second voltage provider circuit is configured to switchably couple the first reference signal line, via an on-chip connection, with the second reference signal line of the second voltage provider circuit.

6. The integrated circuit according to claim 1, wherein the first voltage provider circuit comprises:
a previous circuit stacking connection,
a subsequent circuit stacking connection,
first reference signal switch configured to switchably connect the first reference signal line of the first voltage provider circuit with the previous circuit stacking connection,
a first routing switch configured to switchably connect the previous circuit stacking connection with the subsequent circuit stacking connection, and
a first sense signal switch configured to switchably connect the subsequent circuit stacking connection with the first power sense input.

7. (canceled)

8. The integrated circuit according to claim 1, wherein the first voltage provider circuit comprises a first differential amplifier,
wherein a first input of the first differential amplifier is coupled with the first power sense input of the first voltage provider circuit,
wherein a second input of the first differential amplifier is coupled with the first reference signal line, and
wherein an output of the first differential amplifier provides an analog control signal for regulating the first voltage.

9-11. (canceled)

12. The integrated circuit according to claim 8, wherein the first voltage provider circuit further comprises a first output unit configured to offset the analog control signal or an amplified version of the analog control signal based on an offset signal.

13-16. (canceled)

17. The integrated circuit according to claim 1 further comprising one or more further voltage provider circuits, wherein a respective voltage provider circuit of the one or more further voltage provider circuits is configured to provide a respective further voltage
based on a respective reference signal, present on a respective reference signal line of the respective further voltage provider circuit.

18. The integrated circuit according to claim 17, wherein the first voltage provider circuit, the second voltage provider circuit, and the one or more further voltage provider circuits are coupled as a stack of voltage provider circuits.

19. The integrated circuit according to claim 18,
wherein at least a first given one of the voltage provider circuits in the stack is configured to switchably couple its power sense input to a reference signal line of a second given one of the voltage provider circuits in the stack, the first given one of the voltage provider circuits and the second given one of the voltage provider circuits being adjacent within the stack.

20-27. (canceled)

28. The integrated circuit according to claim 18, wherein the first voltage provider circuit, the second voltage provider circuit, and the one or more further voltage provider circuits are at least structurally or functionally identical voltage provider circuits.

29. The integrated circuit according to claim 18, wherein the first voltage provider circuit, the second voltage provider circuit, and the one or more further voltage provider circuits, are arranged such that successive voltage provider circuits in the stack provide output voltages in an increasing order.

30-39. (canceled)

40. An automated test equipment for testing a device under test comprising:
an integrated circuit comprising:
a first voltage provider circuit configured to provide a first voltage; and
a second voltage provider circuit configured to provide a second voltage;
wherein the first voltage provider circuit is configured to regulate the first voltage with respect to a first reference signal on a first reference signal line;
wherein the second voltage provider circuit is configured to regulate the second voltage with respect to a second reference signal on a second reference signal line;
wherein the second voltage provider circuit is configured to switchably couple the second reference signal line with a first power sense input of the first voltage provider circuit via an on-chip connection, the second reference signal being determined by a potential of the first power sense input of the first voltage provider circuit; and
wherein the first voltage and the second voltage are coupled with respective device under test connections.

41. A method for testing a device under test, DUT, the method comprising:
providing, with a first voltage provider circuit, a first voltage to the DUT and regulating the first voltage with respect to a first reference signal on a first reference signal line of the first voltage provider circuit;
providing, with a second voltage provider circuit, a second voltage to the DUT and regulating the second voltage with respect to a second reference signal on a second reference signal line of the second voltage provider circuit; and
switchably coupling the second reference signal line with a first power sense input of the first voltage provider circuit via an on-chip connection, the second reference signal being determined by a potential of the first power sense input of the first voltage provider circuit.

42. The automated test equipment of claim 40, wherein the first voltage provider circuit is configured to switchably couple the second reference signal line with the first power sense input of the first voltage provider circuit via an on-chip connection, the second reference signal being determined by a potential of the first power sense input of the first voltage provider circuit.

43. The automated test equipment of claim 40,
wherein the first voltage provider circuit is further configured to switchably couple the first reference signal line, via an on-chip connection, with a first ground sense input of the first voltage provider circuit; or
wherein the second voltage provider circuit is further configured to switchably couple the second reference signal line, via an on-chip connection, with a second ground sense input of the second voltage provider circuit.

44. The automated test equipment of claim 43, wherein the first voltage provider circuit and the second voltage provider circuit are configured to switchably couple respective reference signal lines with a shared common ground reference line of the integrated circuit.

45. The automated test equipment of claim 40, wherein the first voltage provider circuit or the second voltage provider circuit is configured to switchably couple the first reference signal line, via an on-chip connection, with the second reference signal line of the second voltage provider circuit.

46. The automated test equipment of claim 40, wherein the first voltage provider circuit, the second voltage provider circuit, and one or more further voltage provider circuits are coupled as a stack of voltage provider circuits.
